(19) United States
(12) Patent Application Publication
(10) Pub. No.: US 2026/0172042 A1
(43) Pub. Date: Jun. 18, 2026

(54) ANALOG-TO-DIGITAL CONVERSION CIRCUITS AND METHODS, CHIPS, AND ELECTRONIC DEVICES

(71) Applicant: CHIPSEA TECHNOLOGIES (SHENZHEN) CORP., Shenzhen (CN)

(72) Inventors: Wenjie YIN, Shenzhen (CN); Weizheng HAO, Shenzhen (CN); Weihui LIU, Shenzhen (CN)

(21) Appl. No.: 19/531,842

(22) Filed: Feb. 6, 2026

Related U.S. Application Data
(63) Continuation of application No. PCT/CN2024/143586, filed on Dec. 30, 2024.

(30) Foreign Application Priority Data
Jan. 2, 2024 (CN) 202410006718.5

(51) Int. Cl. H03M 1/10

(52) U.S. Cl. CPC H03M 1/1014

(57) ABSTRACT

An analog-to-digital conversion circuit includes: a digital-to-analog conversion capacitor array; a calibration capacitor array for calibrating the digital-to-analog conversion capacitor array; and a logic controller for selecting the digital-to-analog conversion capacitor array and the calibration capacitor array based on a range control signal to sample and/or convert an analog input signal, to reduce or increase the analog input signal according to a ratio corresponding to the range control signal.

### CROSS-REFERENCE TO RELATED APPLICATIONS

This application is a continuation of International Application No. PCT/CN2024/143586, filed on Dec. 30, 2024, which claims priority to Chinese Patent Application No. 202410006718.5, filed on Jan. 2, 2024. The disclosures of the abovementioned applications are incorporated herein by reference in their entireties.

### TECHNICAL FIELD

The present application relates to electronic circuit technologies, and in particular to analog-to-digital conversion circuits and methods, chips, and electronic devices.

### BACKGROUND

Before subject to analog-to-digital conversion, an analog input signal, whether bipolar or unipolar, may be expected to be scaled to be within a dynamic range of an analog-to-digital converter (ADC), thereby enabling effective processing of wide-range input signals.

Generally, a resistive divider may be disposed at an analog input of the ADC to scale an analog input signal to be within the dynamic range of the ADC. With this approach, firstly, it is necessary that a source of the analog input signal is able to drive a resistive load; secondly, the resistive divider may consume power from the source of the analog input signal; and thirdly, the range of scaling of the analog input signal is relatively fixed.

### SUMMARY

According to some embodiments of the present application, an analog-to-digital conversion circuit includes: a digital-to-analog conversion capacitor array; a calibration capacitor array for calibrating the digital-to-analog conversion capacitor array; and a logic controller for selecting the digital-to-analog conversion capacitor array and the calibration capacitor array based on a range control signal to sample and/or convert an analog input signal, to reduce or increase the analog input signal according to a ratio corresponding to the range control signal.

According to some embodiments of the present application, a chip includes the above analog-to-digital conversion circuit.

According to some embodiments of the present application, an electronic device includes a device body and the above chip disposed in the device body.

According to some embodiments of the present application, an analog-to-digital conversion method includes: selecting, based on a range control signal, a digital-to-analog conversion capacitor array and a calibration capacitor array to sample and/or convert an analog input signal, to reduce or increase the analog input signal according to a ratio corresponding to the range control signal, where the calibration capacitor array is used for calibrating the digital-to-analog conversion capacitor array.

### BRIEF DESCRIPTION OF THE DRAWINGS

FIG. 1 shows a schematic block diagram of an example of an analog-to-digital conversion circuit according to some embodiments of the present application.

FIG. 2A schematically shows a digital-to-analog conversion capacitor array and a calibration capacitor array according to some embodiments of the present application.

FIG. 2B schematically shows an exemplary combination of a digital-to-analog conversion capacitor array and a calibration capacitor array according to some embodiments of the present application.

FIGS. 2C and 2D schematically show equivalents of exemplary combinations of a digital-to-analog conversion capacitor array and a calibration capacitor array according to some embodiments of the present application.

FIG. 3A to 3C schematically show selection of a digital-to-analog conversion capacitor array and a calibration capacitor array to increase analog input signals according to some embodiments of the present application.

FIG. 4 shows a schematic block diagram of another example of an analog-to-digital conversion circuit according to some embodiments of the present application.

FIG. 5 shows a schematic block diagram of yet another example of an analog-to-digital conversion circuit according to some embodiments of the present application.

FIG. 6A to 6D schematically show exemplary combinations of a digital-to-analog conversion capacitor array and a calibration capacitor array according to some embodiments of the present application.

FIG. 7 shows a flowchart of an example of an analog-to-digital conversion method according to some embodiments of the present application.

FIG. 8 shows a flowchart of another example of an analog-to-digital conversion method according to some embodiments of the present application.

### DETAILED DESCRIPTION

The embodiments of the present application are described in detail below. Examples of the embodiments are shown in the accompanying drawings, where the same or similar reference numerals denote the same or similar elements or elements having the same or similar functions throughout. The embodiments described below with reference to the accompanying drawings are exemplary and are only used to illustrate the present application, and should not be construed as limiting the present application.

To enable those skilled in the art to better understand the solutions of the present application, the technical solutions of the embodiments of the present application will be clearly and completely described below with reference to the accompanying drawings. Obviously, the described embodiments are only a part of the embodiments of the present application, and not all of them. All other embodiments obtained by those skilled in the art based on the embodiments of the present application without creative effort are within the scope of protection of the present application.

In the embodiments of the present application, it should be noted that relational terms here such as first and second are used only to distinguish one entity or operation from another entity or operation, and do not necessarily require or imply any such actual relationship or order between these entities or operations.

Furthermore, the terms “comprising”, “including” or any other variations thereof are intended to cover non-exclusive inclusion, such that a process, method, article, or apparatus that comprises a list of elements includes not only those elements but also other elements not expressly listed, or elements inherent to such a process, method, article, or apparatus. Without further limitation, an element defined by the phrase “comprising a . . . ” does not exclude the presence of other identical elements in the process, method, article, or apparatus that includes said element.

In the description of the embodiments of the present application, the words “example” or “for example” are used to indicate exemplification, illustration, or description. Any embodiment or design described as “example” or “for example” in the embodiments of the present application is not to be construed as being more preferred or having more advantages than another embodiment or design. The use of the words “example” or “for example” is intended to present relative concepts in a clear manner.

Furthermore, in the embodiments of the present application, “a plurality of” refers to two or more. Therefore, in the embodiments of the present application, “a plurality of” may also be understood as “at least two”. “At least one” may be understood as one or more, such as one, two, or more. For example, including at least one means including one, two, or more, and is not limited to which ones are included. For example, including at least one of A, B or C, then it could include A, B, C, A and B, A and C, B and C, or A and B and C.

It should be noted that in the embodiments of the present application, “and/or” describes the relationship between associated objects, indicating that there may be three relationships. For example, A and/or B may represent: A existing alone, A and B existing simultaneously, or B existing alone. In addition, the character “/”, unless otherwise specified, generally indicates that the associated objects before and after it are in an “or” relationship.

It should be noted that in the embodiments of the present application, “connection” may be understood as electrical connection. The connection between two electrical components may be a direct or indirect connection between the two electrical components. For example, the connection between A and B may be a direct connection between A and B, or an indirect connection between A and B through one or more other electrical components.

The present application provides analog-to-digital conversion circuits that may achieve a wider range of reduction or increasement of analog input signals with a smaller circuit area.

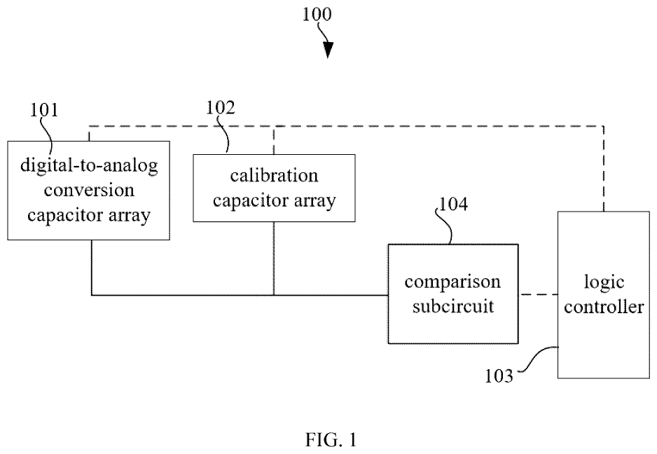

FIG. 1 shows a schematic block diagram of an analog-to-digital conversion circuit according to some embodiments of the present application. As shown in FIG. 1, the analog-to-digital conversion circuit 100 may include a digital-to-analog conversion capacitor array 101, a calibration capacitor array 102, a logic controller 103, and a comparison subcircuit 104. The logic controller 103 may monitor the output of the comparison subcircuit 104. The calibration capacitor array 102 is used to calibrate the digital-to-analog conversion capacitor array 101.

In the embodiments, the logic controller 103 may be configured to select the digital-to-analog conversion capacitor array 101 and the calibration capacitor array 102 based on the range control signal to sample and/or convert the analog input signal, so as to reduce or increase the analog input signal according to the ratio corresponding to the range control signal. For example, to increase or reduce the analog input signal to match the dynamic range of the analog-to-digital conversion circuit 100.

In the embodiments, the logic controller 103 may also be configured to control the calibration capacitor array 102 to perform calibration based on a calibration code. As an implementation, the quantity to be calibrated is the actual capacitance of each of a plurality of capacitor sets respectively corresponding to a plurality of capacitance bits in the digital-to-analog conversion capacitor array 101. During the calibration phase, the capacitance mismatch value is expressed as an error voltage output by the digital-to-analog conversion capacitor array 101. The calibration capacitor array 102 measures the value of this error voltage and saves the result as the calibration code. During the operation phase, the calibration capacitor array 102 loads the error voltage onto the output of the digital-to-analog conversion capacitor array 101 by connecting different capacitors.

In the embodiments, the smaller the capacitance for sampling the analog input signal, the greater the reduction ratio; the larger the capacitance for sampling the analog input signal, the greater the increasement ratio; and the larger the capacitance for conversion, the greater the reduction ratio. In some examples, the capacitance for sampling may be increased by multiplexing the calibration capacitor array 102 to increase the analog input signal. In some examples, the capacitance for conversion may be increased by multiplexing the calibration capacitor array 102 to reduce the analog input signal. In some examples, the analog input signal may be reduced by decreasing the capacitance for sampling and increasing the capacitance for conversion by multiplexing the calibration capacitor array 102, thereby increasing the reduction ratio of the analog input signal, i.e., reducing the analog input signal to a smaller size. Furthermore, combination of various capacitances for sampling and various capacitances for conversion may provide various reduction or increasement ratios, and more combinations may be achieved by multiplexing the calibration capacitor array 102, providing more reduction or increasement ratios.

In some implementations, the logic controller 103 may: during the conversion phase, select at least one capacitor in the calibration capacitor array 102 to be combined to individual capacitor sets in the digital-to-analog conversion capacitor array 101 based on the range control signal to increase the capacitance of each capacitor sets in the digital-to-analog conversion capacitor array 101; and control the combined capacitor sets to perform conversion. This implementation may reduce the analog input signal according to the ratio corresponding to the range control signal.

In one implementation, the logic controller 103 may select the at least one capacitor from at least one of a plurality of capacitor sets respectively corresponding to a plurality capacitance bits in the calibration capacitor array 102 based on a range control signal, and combine it with each of capacitor sets in the digital-to-analog conversion capacitor array 101. Thus, other unselected capacitor sets in the calibration capacitor array 102 may be used for calibration.

In some embodiments, the logic controller 103 may further: during the sampling phase, select capacitors in the calibration capacitor array 102 and/or the digital-to-analog conversion capacitor array 101 based on the range control signal to sample the analog input signal. In this embodiment, by selecting the capacitance for sampling and the capacitance for conversion based on the range control signal, the analog input signal may be reduced according to the ratio corresponding to the range control signal.

As an example, during the sampling phase, one or more capacitors in the digital-to-analog conversion capacitor array 101 may be selected based on a range control signal to sample the analog input signal. The smaller the capacitance of the selected capacitor, the greater the reduction ratio; that is, the smaller the capacitance for sampling, the smaller the analog-to-digital input signal is reduced. In this example, the calibration capacitor array 102 may be controlled based on a calibration code for calibration during the conversion phase.

As another example, during the sampling phase, one or more capacitors in the calibration capacitor array 102 may be selected based on a range control signal to sample the analog input signal. The smaller the capacitance of the selected capacitor, the greater the reduction ratio; that is, the smaller the capacitance or sampling, the smaller the analog-to-digital input signal is reduced. In this example, the calibration capacitor array 102 may be controlled for calibration based on a calibration code during the conversion phase.

As yet another example, during the sampling phase, one or more capacitors in the digital-to-analog conversion capacitor array 101 and one or more capacitors in the calibration capacitor array 102 may be selected based on a range control signal to sample the analog input signal. The smaller the capacitance of the selected capacitor, the greater the reduction ratio; that is, the smaller the capacitance for sampling, the smaller the analog-to-digital input signal is reduced. In this example, calibration capacitor array 102 may be controlled based on a calibration code for calibration during the conversion phase.

In some implementations, the logic controller 103 may: during the sampling phase, select capacitors in the calibration capacitor array 102 and/or the digital-to-analog conversion capacitor array 101 based on the range control signal to sample the analog input signal; during the conversion phase, select at least one of capacitors in the calibration capacitor array 102 and combine it to individual capacitor sets of the digital-to-analog conversion capacitor array 101 based on the range control signal to increase the capacitance of each capacitor sets in the digital-to-analog conversion capacitor array 101; and control the combined capacitor sets to perform conversion. In this implementation, the reduction ratio is jointly determined by the capacitance for sampling and the capacitance for conversion, enabling the analog input signal to be reduced according to the ratio corresponding to the range control signal.

In one implementation, the logic controller 103 may: during the conversion phase, connect the capacitor set corresponding to the capacitance bit in the digital-to-analog conversion capacitor array 101 to a reference voltage terminal, and connect the capacitor combined with it in the calibration capacitor array 102 to the reference voltage terminal; or ground the capacitor set corresponding to the capacitance bit in the digital-to-analog conversion capacitor array 101, and ground the capacitor combined with it in the calibration capacitor array 102.

As an example, the logic controller 103 may select a capacitor of at least one of capacitor sets in the calibration capacitor array 102 based on a range control signal, and combine it with the respective capacitor sets in the digital-to-analog conversion capacitor array 101. Exemplarily, each capacitor set in the calibration capacitor array 102 may include multiple capacitors, and a capacitor of at least one capacitor sets in the calibration capacitor array 102 may be assigned to each capacitor set of the digital-to-analog conversion capacitor array 101 to adjust the capacitance of each capacitor set in the digital-to-analog conversion capacitor array 101.

For example, taking a binary capacitor array as an example, the capacitance of each capacitor set in the digital-to-analog conversion capacitor array 101 are 8C, 4C, 2C, and 1C, respectively, where C represents a certain capacitance. In the calibration capacitor array 102, one capacitor set includes multiple capacitors, with the capacitances of the multiple capacitors contained in the capacitor set corresponding to the highest capacitance bit being 4C, 2C, C, 0.5C and 0.5C, respectively. The capacitors contained in the capacitor set corresponding to the highest capacitance bit may be combined with the capacitor set in the digital-to-analog conversion capacitor array 101. After combination, the capacitances of each capacitor sets in the digital-to-analog conversion capacitor array 101 are: 12C (i.e., 8C+4C), 6C (i.e., 4C+2C), 3C (i.e., 2C+C), 1.5C (i.e., 1C+0.5C) and 1.5C (i.e., 1C+0.5C), in order. In this example, the capacitance ratios between the capacitor sets in the digital-to-analog conversion capacitor array 101 are the same before and after the combination.

In this example, during the conversion phase, if the capacitor contained in the capacitor set corresponding to the highest capacitance bit (capacitance of 8C) in the digital-to-analog conversion capacitor array 101 is connected to the reference voltage terminal, then the capacitor contained in the capacitor set corresponding to the highest capacitance bit, with a capacitance of 4C, in the calibration capacitor array 102 is connected to the reference voltage terminal. That is, during the conversion phase, the capacitance of the capacitor set corresponding to the highest capacitance bit in the digital-to-analog conversion capacitor array 101 increases from 8C to 12C; if the capacitor contained in the capacitor set corresponding to the highest capacitance bit (capacitance of 8C) in the digital-to-analog conversion capacitor array 101 is grounded, then the capacitor contained in the capacitor set corresponding to the highest capacitance bit, with a capacitance of 4C, in the calibration capacitor array 102 is grounded. Similarly, if the capacitor contained in the capacitor set corresponding to the second highest capacitance bit (capacitance of 4C) in the digital-to-analog conversion capacitor array 101 is connected to the reference voltage terminal, then the capacitor in the capacitor set corresponding to the second highest capacitance bit, with a capacitance of 2C, in the calibration capacitor array 102 is connected to the reference voltage terminal. That is, during the conversion phase, the capacitance of the capacitor set corresponding to the second highest capacitance bit in the digital-to-analog conversion capacitor array 101 increases from 4C to 6C; if the capacitor contained in in the capacitor set corresponding to the second highest capacitance bit (capacitance of 4C) in the digital-to-analog conversion capacitor array 101 is grounded, then the capacitor contained in the capacitor set corresponding to the second highest capacitance bit, with a capacitance of 2C, in the calibration capacitor array 102 is grounded.

In some implementations, the logic controller 103 may also control the unselected capacitor sets in the calibration capacitor array 102 based on the calibration code. For example, the calibration capacitor array 102 includes four calibration capacitor set. The capacitor set corresponding to the highest capacitance bit of the calibration capacitor array 102 is multiplexed to scale the analog input signal, and the remaining three calibration capacitor sets of the calibration capacitor array 102 may be used for calibration. For example, if the calibration code is 0010, then the remaining three calibration capacitor sets of the calibration capacitor array 102 are controlled based on the last three bits “010” of the calibration code to perform calibration.

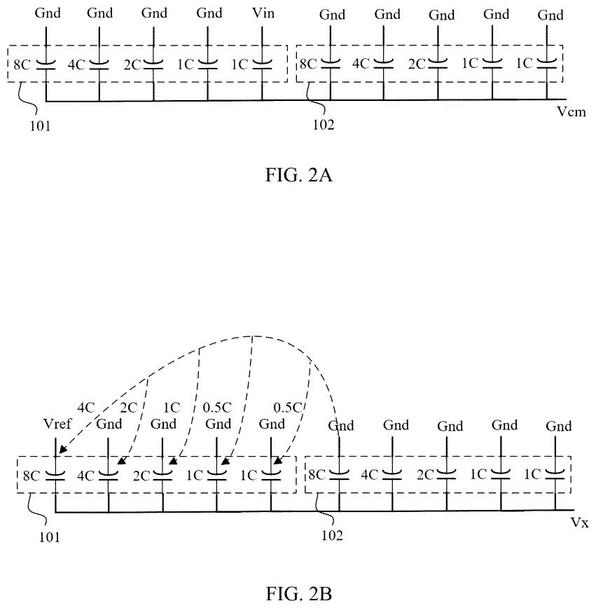

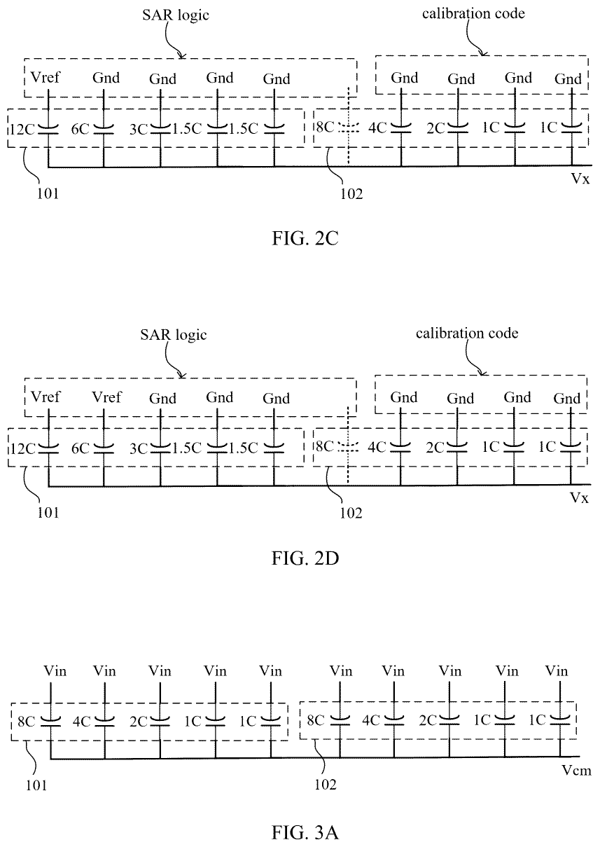

Referring to FIGS. 2A, 2B, 2C, and 2D, an example of reducing an analog input signal is shown. The digital-to-analog conversion capacitor array 101 and the calibration capacitor array 102 each include five capacitor sets, with capacitance of 8C, 4C, 2C, 1C, and 1C, respectively. In this example, the analog input signal is increased by reducing the capacitance for sampling and increasing the capacitance for conversion by multiplexing the calibration capacitor array 102.

During the sampling phase, the logic controller 103 may select a capacitor set with a capacitance of 1C in the digital-to-analog conversion capacitor array 101 to sample the analog input signal. It should be understood that selecting a capacitor set with a capacitance of 1C is merely an example; for instance, capacitor sets with capacitances of 2C, 4C, or 8C may also be selected for sampling the analog input signal. In this example, sampling the analog input signal using a capacitor set with a capacitance of 1C is used for illustration. As shown in FIG. 2A, an end of the digital-to-analog conversion capacitor array 101 connected to the input terminal of the comparison subcircuit 104 receives the common-mode voltage Vcm. The capacitor set with a capacitance of 1C in the digital-to-analog conversion capacitor array 101 receives the analog input signal Vin, and the analog input signal Vin is sampled through this capacitor set; that is, the capacitance for sampling is 1C. An end of the calibration capacitor array 102 connected to the input terminal of the comparison subcircuit 104 may receive the common-mode voltage Vcm, and another end of the calibration capacitor array 102 may be grounded.

After the sampling, the charge magnitude Q₂₁ of the digital-to-analog conversion capacitor array 101 and the calibration capacitor array 102 satisfies:

$$\begin{matrix}{Q}_{21} = ( Vcm - Vin ) \times 1 C + ( Vcm - 0 ) \times \\ ( 8 C + 4 C + 2 C + 1 C + 8 C + 4 C + 2 C + 1 C + 1 C ) \\ = 32 C \times Vcm - Vin \times 1 C ,\end{matrix} \qquad ( 1 )$$

where Vin represents the analog input voltage and Vcm represents the common-mode voltage.

During the conversion phase, the capacitor contained in a capacitor set with a capacitance of 8C in the calibration capacitor array 102 may be assigned to the digital-to-analog conversion capacitor array 101. It should be understood that assigning the capacitor contained in the capacitor set with a capacitance of 8C to the digital-to-analog conversion capacitor array 101 is merely an example; for instance, the capacitor contained in a capacitor set with a capacitance of 4C in the calibration capacitor array 102 may also be assigned to the digital-to-analog conversion capacitor array 101. As shown in FIG. 2B, according to the capacitance ratio between capacitor sets in the digital-to-analog conversion capacitor array 101, the capacitance of 8C of the capacitor sets in the calibration capacitor array 102 are divided into: 4C, 2C, 1C, 0.5C, and 0.5C, which are combined to the capacitor sets in the digital-to-analog conversion capacitor array 101, respectively. As shown in FIG. 2C, after the combination, the equivalent capacitance of each capacitor sets in the digital-to-analog conversion capacitor array 102 is 12C (i.e., 8C+4C), 6C (i.e., 4C+2C), 3C (i.e., 2C+1C), 1.5C (i.e., 1C+0.5C), and 1.5C (i.e., 1C+0.5C).

During the conversion phase, the logic controller 103 may control the combined capacitor sets for conversion, specifically controlling the capacitor set with the capacitance of 8C in the digital-to-analog conversion capacitor array 101 and the capacitor set with the capacitance of 8C in the calibration capacitor array 102. In one embodiment, the remaining capacitor sets in the calibration capacitor array 102 may be controlled based on a calibration code. To facilitate the explanation of the scaling process for the analog input signal, the following are illustrated with grounding the remaining capacitor sets of the calibration capacitor array 102, as an example.

For example, the logic controller 103 may perform successive approximation register (SAR) logic, such as binary search.

In the binary search, as shown in FIG. 2C, the capacitor set corresponding to the highest capacitance bit obtained by combination (capacitance of 12C) is connected to the reference voltage terminal (providing a reference voltage Vref). That is, the capacitor contained in the capacitor set corresponding to the highest capacitance bit (capacitance of 8C) in the digital-to-analog conversion capacitor array 101 is connected to the reference voltage terminal, and the capacitor contained in the capacitor set, with a capacitance of 4C, corresponding to the highest capacitance bit of the calibration capacitor array 102 is connected to the reference voltage terminal. At this time, the charge magnitude Q₂₂ of the digital-to-analog conversion capacitor array 101 and the calibration capacitor array 102 satisfies:

$$\begin{matrix}{Q}_{22} = ( Vx - Vref ) \times 12 C + ( Vx - 0 ) \times ( 6 C + 3 C + 1.5 C + 1.5 C ) + \\ ( Vx - 0 ) \times ( 4 C + 2 C + 1 C + 1 C ) \\ = Vx \times 32 C - Vref \times 12 C ,\end{matrix} \qquad ( 2 )$$

where Vx represents the voltage input to the comparison subcircuit 104 from the digital-to-analog conversion capacitor array 101 and the calibration capacitor array 102, and Vref represents the reference voltage.

According to the law of charge conservation, Q₂₁=Q₂₂, therefore:

$$Vx = Vcm - 3 / 4 \times ( 1 / 24 \times Vin - 1 / 2 \times Vref ) . \qquad ( 3 )$$

In one implementation, taking the highest capacitance bit being “1” as an example, as shown in FIG. 2D, the logic controller 103 connects the combined capacitor set corresponding to the highest capacitance bit to the reference voltage terminal. A binary search is performed, as shown in FIG. 2D, connecting the combined capacitor set corresponding to the second highest capacitance bit (capacitance of 6C) to the reference voltage terminal. That is, the capacitor contained in the capacitor set corresponding to the second highest capacitance bit (capacitance of 4C) in the digital-to-analog conversion capacitor array 101 is connected to the reference voltage terminal, and the capacitor in the capacitor set, with a capacitance of 2C, corresponding to the highest capacitor capacitance bit in the calibration capacitor array 102 is connected to the reference voltage terminal. At this time, the charge magnitude Q₂₃ of the digital-to-analog conversion capacitor array 101 and the calibration capacitor array 102 satisfies:

$$\begin{matrix}{Q}_{23} = ( Vx - Vref ) \times 18 C + ( Vx - 0 ) \times \\ ( 3 C + 1.5 C + 1.5 C ) + ( Vx - 0 ) \times \\ ( 4 C + 2 C + 1 C + 1 C ) \\ = Vx \times 32 C - Vref \times 18 C .\end{matrix} \qquad ( 4 )$$

According to the law of charge conservation, Q₂₁=Q₂₃, therefore:

$$Vx = Vcm - 3 / 4 \times ( 1 / 24 \times Vin - 1 / 2 \times Vref - 1 / 4 \times Vref ) . \qquad ( 5 )$$

Similarly, during the conversion phase:

$$Vx = Vcm - \frac{3}{4} ( \frac{1}{24} \times Vin - {\sum }_{i = 0}^{3} \frac{Vref}{{2}^{4 - i}} \times Di ) , \qquad ( 6 )$$

where Di represents the code value of the i-th capacitance bit, which corresponds to the capacitor set in the digital-to-analog conversion capacitor array 101 controlled by the logic controller 103, with the highest capacitance bit i being 3, the second highest capacitance bit i being 2, and so on.

Therefore, in the examples shown in FIGS. 2A to 2D, the analog input signal is reduced to 1/24 of its original value.

It should be understood that FIGS. 2A to 2D are merely examples for illustration. In the embodiments of the present application, the scaling ratio may be adjusted by selecting the capacitance for sampling and/or controlling capacitance for conversion. The present application will not elaborate further on this aspect.

In some implementations, the logic controller 103 may, during the sampling phase, select capacitors in the digital-to-analog conversion capacitor array 101 and the calibration capacitor array 102 for sampling based on a range control signal, so as to increase the analog input signal according to the ratio corresponding to the range control signal; and during the conversion phase, it may control each capacitor sets of the digital-to-analog conversion capacitor array 101 to perform conversion. In these implementations, the larger the capacitance for sampling, the greater the increasement factor of the analog input signal, and various capacitances for sampling may correspond to various increasement factors. As an implementation, the logic controller 103 may also control the calibration capacitor array 102 based on a calibration code to perform calibration.

As an exemplary illustration, when all capacitor sets in the digital-to-analog conversion capacitor array 101 are used to sample and convert the analog input signal, it may be assumed that the analog input signal is neither reduced nor increased, i.e., the gain is 1. If all capacitor sets in the digital-to-analog conversion capacitor array 101 are used to sample the analog input signal, and capacitors in the calibration capacitor array 102 are selected to sample the analog input signal, the analog input signal may be increased, i.e., the gain is greater than 1. The increasement ratio is positively correlated with the capacitance for sampling.

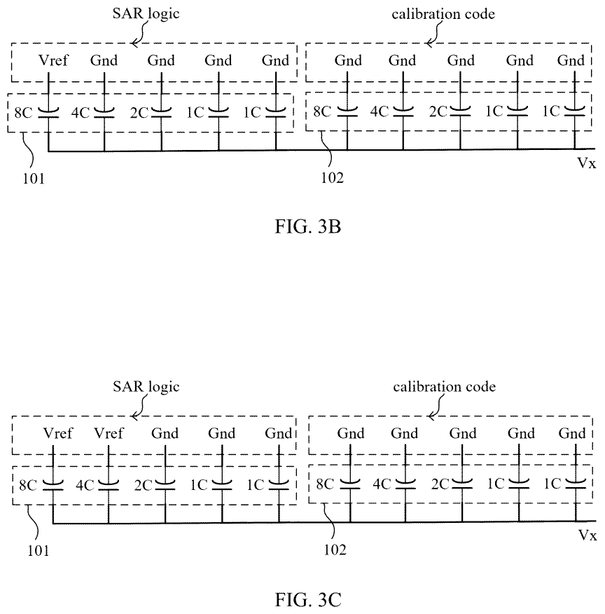

For example, as shown in FIGS. 3A, 3B, and 3C, the digital-to-analog conversion capacitor array 101 includes five capacitor sets each with a capacitance of 8C, 4C, 2C, 1C and 1C, respectively. The calibration capacitor array 102 includes five capacitor sets each with a capacitance of 8C, 4C, 2C, 1C and 1C, respectively.

During the sampling phase, the logic controller 103 may select capacitors from the digital-to-analog conversion capacitor array 101 and the calibration capacitor array 102 to sample the analog input signal Vin. For example, as shown in FIG. 3A, all capacitors in the digital-to-analog conversion capacitor array 101 and the calibration capacitor array 102 are selected to sample the analog input signal Vin, that is, all capacitors receive the analog input signal Vin. At this time, the charge magnitude Q₃₁ of the digital-to-analog conversion capacitor array 101 and the calibration capacitor array 102 satisfies:

$$\begin{matrix}{Q}_{31} = ( Vcm - Vin ) \times \\ ( 8 C + 4 C + 2 C + 1 C + 1 C + 8 C + 4 C + 2 C + 1 C + 1 C ) \\ = ( Vcm - Vin ) \times 32 C .\end{matrix} \qquad ( 7 )$$

During the conversion phase, the logic controller 103 may control the digital-to-analog conversion capacitor array 101 to perform the conversion. For example, the logic controller 103 may perform SAR logic, such as a binary search. In one embodiment, the logic controller 103 may control the calibration capacitor array 102 based on a calibration code during the conversion phase. For ease of illustration regarding scaling of the analog input signal, the following description assumes the calibration capacitor array 102 is grounded (i.e., no calibration is performed).

In the binary search, referring to FIG. 3B, the capacitor set corresponding to the highest capacitance bit in the digital-to-analog conversion capacitor array 101 is connected to the reference voltage terminal, and the remaining capacitor sets are grounded. The calibration capacitor array 102 is grounded (i.e., no calibration is performed). At this time, the charge magnitude Q₃₂ of the digital-to-analog conversion capacitor array 101 and the calibration capacitor array 102 satisfy:

$$\begin{matrix}{Q}_{32} = ( Vx - Vref ) \times 8 C + ( Vx - 0 ) \times \\ ( 4 C + 2 C + 1 C + 1 C + 8 C + 4 C + 2 C + 1 C + 1 C ) \\ = Vx \times 32 C - Vref \times 8 C ,\end{matrix} \qquad ( 8 )$$

where Vx represents the voltage output from the digital-to-analog conversion capacitor array 101 and the calibration capacitor array 102 to the comparison subcircuit 104.

According to the law of charge conservation, Q₃₂=Q₃₁, therefore:

$$Vx = Vcm - 1 / 2 ( 2 \times Vin - 1 / 2 \times Vref ) . \qquad ( 9 )$$

In one embodiment, taking the highest capacitance bit being 1 as an example, as shown in FIG. 3C, the capacitor sets corresponding to the highest and second highest capacitance bits of the digital-to-analog conversion capacitor array 101 are connected to a reference voltage terminal, while the remaining capacitor sets are grounded. The calibration capacitor array 102 is grounded (i.e., no calibration is performed). At this time, the charge magnitude Q₃₃ of the digital-to-analog conversion capacitor array 101 and the calibration capacitor array 102 satisfies:

$$\begin{matrix}{Q}_{33} = ( Vx - Vref ) \times ( 8 C + 4 C ) + ( Vx - 0 ) \times \\ ( 2 C + 1 C + 1 C + 8 C + 4 C + 2 C + 1 C + 1 C ) \\ = Vx \times 32 C - Vref \times 12 C .\end{matrix} \qquad ( 10 )$$

According to the law of charge conservation, Q₃₃=Q₃₁, therefore:

$$Vx = Vcm - 1 / 2 \times ( 2 \times Vin - 1 / 2 \times Vref - 1 / 4 \times Vref ) . \qquad ( 11 )$$

Similarly, during the conversion phase:

$$Vx = Vcm - \frac{1}{2} ( 2 \times Vin - {\sum }_{i = 0}^{3} \frac{Vref}{{2}^{4 - i}} \times Di ) , \qquad ( 12 )$$

where Di represents the code value of the i-th capacitance bit, which corresponds to the capacitor set in the digital-to-analog conversion capacitor array 101 controlled by the logic controller 103, with the highest capacitor capacitance bit i being 3, the second highest capacitor capacitance bit i being 2, and so on.

Therefore, in the examples shown in FIGS. 3A to 3C, the analog input signal was increased by a factor of 2.

It should be understood that FIGS. 3A to 3C are merely examples for illustration. In this embodiment, the increasement factor of the analog input signal may be adjusted by adjusting the capacitance for sampling the analog input signal in the digital-to-analog conversion capacitor array 101 and the calibration capacitor array 102. For example, for a smaller increasement factor, some capacitor sets in the calibration capacitor array 102 may be selected for sampling, while for a larger increasement factor, more capacitor sets in the calibration capacitor array 102 may be selected for sampling.

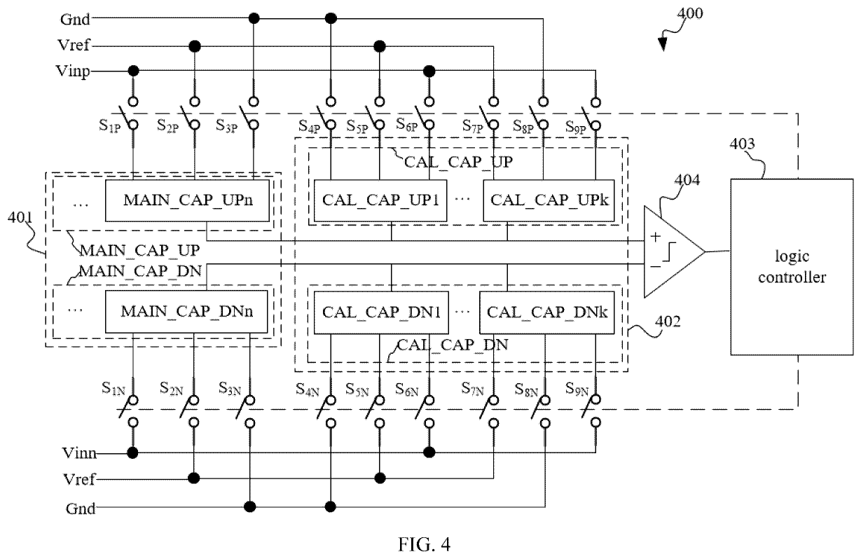

FIG. 4 shows a schematic block diagram of another analog-to-digital conversion circuit according to some embodiments of the present application. As shown in FIG. 4, the analog-to-digital conversion circuit 400 may include a digital-to-analog conversion capacitor array 401, a calibration capacitor array 402, a logic controller 403, and a comparison subcircuit 404. As shown in FIG. 4, the digital-to-analog conversion capacitor array 401 has an output terminal connected to the input terminal of the comparison subcircuit 404. The calibration capacitor array 402 has an output terminal connected to the input terminal of the comparison subcircuit 404. The logic controller 403 may monitor the output of the comparison subcircuit 404. In this embodiment, the analog input signal may be scaled using the digital-to-analog conversion capacitor array 401 and the calibration capacitor array 402, for example, scaling the analog input signal to the dynamic range of the analog-to-digital conversion circuit 400.

For example, as shown in FIG. 4, the digital-to-analog conversion capacitor array 401 may include a positive terminal main capacitor array (referred to as MAIN CAP) MAIN_CAP_UP and a negative terminal main capacitor array MAIN_CAP_DN. The positive terminal main capacitor array MAIN_CAP_UP and the negative terminal main capacitor array MAIN_CAP_DN each include N capacitor sets. For simplicity, only capacitor sets MAIN_CAP_UPn and MAIN_CAP_DNn are shown in FIG. 4. The calibration capacitor array (CAL CAP) 402 may include a positive terminal main capacitor array CAL_CAP_UP and a negative terminal main capacitor array CAL_CAP_DN. The positive terminal main capacitor array CAL_CAP_UP and the negative terminal main capacitor array CAL_CAP_DN each include K capacitor sets, and only capacitor sets CAL_CAP_UP1, CAL_CAP_UPk, CAL_CAP_DN1 and CAL_CAP_DNk are shown in FIG. 4.

For example, as shown in FIG. 4, a switching network (Sip to Sop and SIN to SON as shown in FIG. 4) is configured to switch capacitor sets or capacitors to connect to the reference voltage terminal (providing the reference voltage Vref), to receive the analog input signals (Vinp, Vinn), or to connect to ground Gnd.

Referring to FIG. 4, when reducing the analog input signal, the logic controller 403 may, during the conversion phase, select at least one capacitor in the calibration capacitor array 402 to be combined to individual capacitor sets respectively corresponding to capacitance bits in the digital-to-analog conversion capacitor array 401 based on the range control signal to adjust the capacitance of each capacitor set in the digital-to-analog conversion capacitor array 401; and control the combined capacitor sets for conversion. Thus, the calibration capacitor array 402 is multiplexed to reduce the analog input signal, and a large reduction ratio may be achieved with a small circuit area.

When reducing the analog input signal, the logic controller 403 may also select one or more capacitors in the calibration capacitor array 402 and/or the digital-to-analog conversion capacitor array 401 to sample the analog input signal during the sampling phase based on the range control signal. At this time, the reduction ratio of the analog input signal is determined by the capacitance for sampling the analog input signal and the capacitance of each capacitor set after combination. The smaller the capacitance for sampling the analog input signal, the greater the reduction ratio, i.e., the analog input signal is reduced to a smaller size. The larger the capacitance of each capacitor set after combination, the greater the reduction ratio, i.e., the analog input signal is reduced to a smaller size.

As an implementation, when reducing the analog input signal, the logic controller 403 may also control the capacitor sets in the calibration capacitor array 402 that are not combined to the digital-to-analog conversion capacitor array 401 based on the calibration code to perform calibration during the conversion phase. For example, the calibration capacitor array 402 includes four calibration capacitor sets respectively corresponding to four calibration capacitance bits. The capacitor set corresponding to the highest capacitance bit in the calibration capacitor array 402 is multiplexed to reduce the analog input signal, and the remaining three capacitor sets corresponding to other three calibration capacitance bits in the calibration capacitor array 402 may be used for calibration. For example, the calibration code is 0010, then the remaining three capacitor sets corresponding to the three calibration capacitance bits of the calibration capacitor array 402 are controlled based on the last three bits “010” of the calibration code to perform calibration.

Referring to FIG. 4, when increasing the analog input signal, the logic controller 403 may select capacitors in the digital-to-analog conversion capacitor array 401 and the calibration capacitor array 402 for sampling based on the range control signal during the sampling phase, so as to increase the analog input signal according to the ratio corresponding to the range control signal; and during the conversion phase, it may control each capacitor set of the digital-to-analog conversion capacitor array 401 to perform the conversion. Thus, the calibration capacitor array 402 is multiplexed to increase the analog input signal, and a large increasement factor may be achieved with a small circuit area.

As an implementation, when increasing the analog input signal, the logic controller 403 may also control the calibration capacitor array 402 to perform calibration based on the calibration code during the conversion phase.

Referring to FIG. 4, when not scaling the analog input signal, the logic controller 403 may input the analog input signal into the digital-to-analog conversion capacitor array 401 to sample the analog input signal during the sampling phase; and during the conversion phase, it controls the digital-to-analog conversion capacitor array 401 according to SAR logic to perform the conversion, and controls the calibration capacitor array 402 based on the calibration code. For example, the calibration capacitor array 402 includes 4 calibration capacitor sets respectively corresponding to 4 calibration capacitance bits, and an exemplary calibration code is 0010. In this case, the third capacitor set of the calibration capacitor array 402 connects to the reference voltage terminal (providing the reference voltage Vref) and the remaining capacitor sets are grounded for calibration.

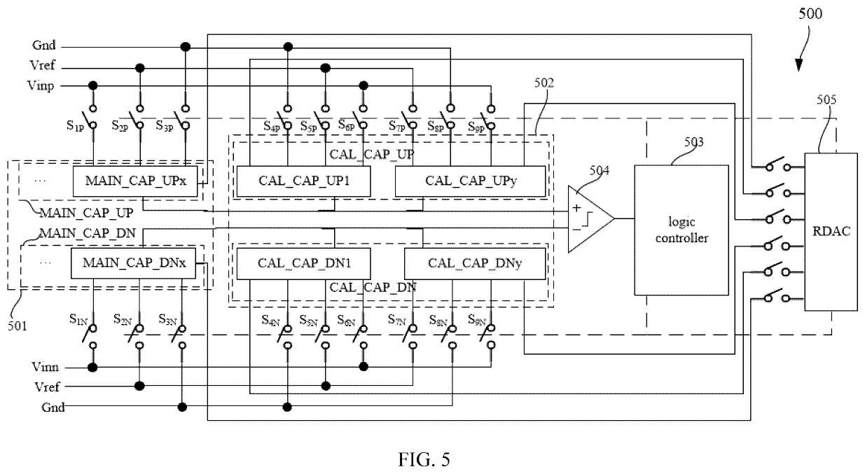

FIG. 5 shows a schematic block diagram of yet another analog-to-digital converter circuit according to some embodiments of the present application. As shown in FIG. 5, the analog-to-digital conversion circuit 500 may include a digital-to-analog conversion capacitor array 501, a calibration capacitor array 502, a logic controller 503, a comparison subcircuit 504, and a resistive digital-to-analog converter (RDAC) 505. The digital-to-analog conversion capacitor array 501 and the RDAC 505 constitute a capacitor-resistor hybrid digital-to-analog converter. The logic controller 503 may monitor the output of the comparison subcircuit 504.

For example, as shown in FIG. 5, the digital-to-analog conversion capacitor array 501 may include a positive terminal main capacitor array (referred to as MAIN CAP) MAIN_CAP_UP and a negative terminal main capacitor array MAIN_CAP_DN. The positive terminal main capacitor array MAIN_CAP_UP and the negative terminal main capacitor array MAIN_CAP_DN each include X capacitor sets. For simplicity, only capacitor sets MAIN_CAP_UPx and MAIN_CAP_DNx are shown in FIG. 5. The calibration capacitor array (CAL CAP) 502 may include a positive terminal main capacitor array CAL_CAP_UP and a negative terminal main capacitor array CAL_CAP_DN. The positive terminal main capacitor array CAL_CAP_UP and the negative terminal main capacitor array CAL_CAP_DN each include Y capacitor sets, and only capacitor sets CAL_CAP_UP1, CAL_CAP_UPy, CAL_CAP_DN1 and CAL_CAP_DNy are shown in FIG. 5.

For example, as shown in FIG. 5, a switching network (Sip to Sop and SIN to SON as shown in FIG. 5) is configured to switch capacitor sets or capacitors to connect to the reference voltage terminal (providing the reference voltage Vref), to receive the analog-to-digital input signals (Vinp, Vinn), or to connect to ground Gnd.

In this embodiment, the analog input signal may be scaled using the digital-to-analog conversion capacitor array 501 and the calibration capacitor array 502, for example, scaling the analog input signal to the dynamic range of the analog-to-digital conversion circuit 500. The logic controller 503 controls the digital-to-analog conversion capacitor array 501 and the calibration capacitor array 502 to scale the analog input signal, as described above in this specification, and will not be repeated here.

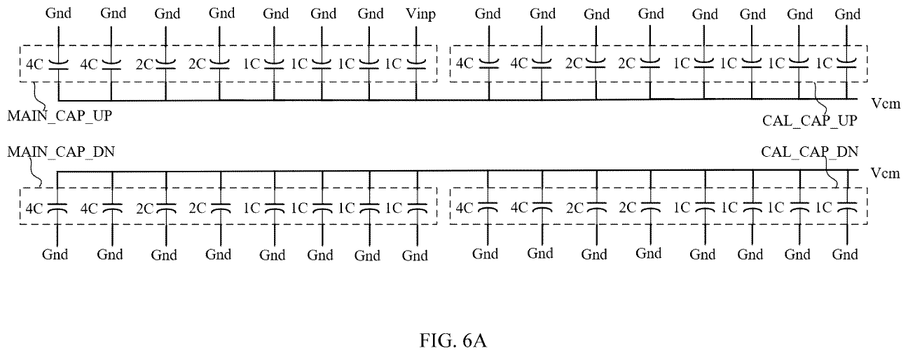

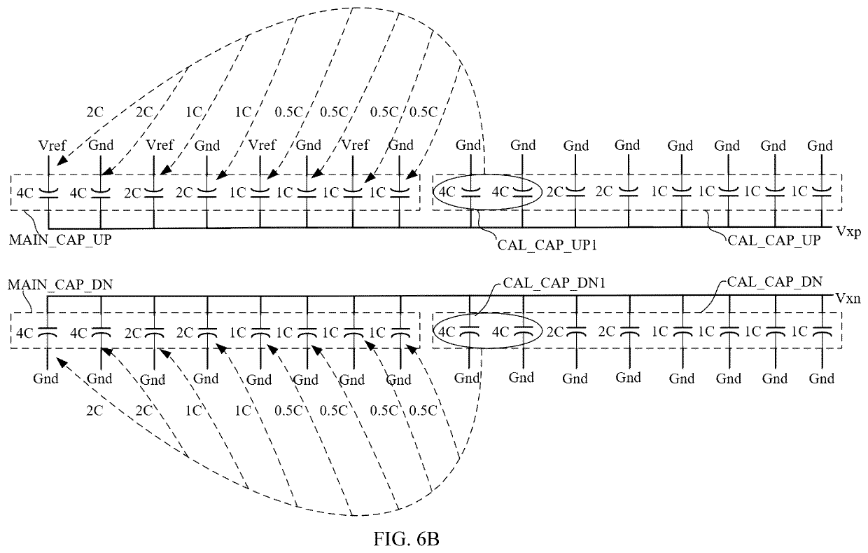

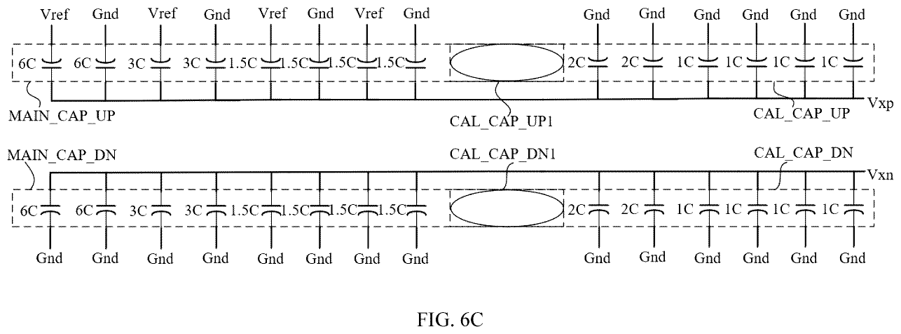

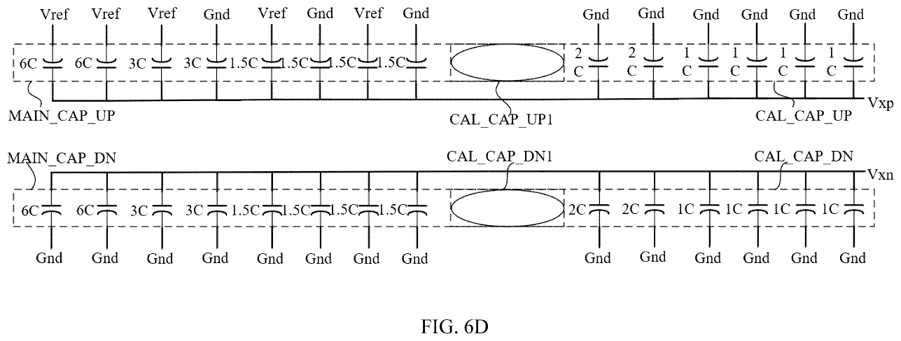

Referring to FIGS. 6A, 6B, 6C and 6D, the main capacitor array and calibration capacitor array in FIG. 4 or FIG. 5 may employ a split capacitor structure. For example, as shown in FIGS. 6A to 6D, each capacitor set may consist of two split capacitor sets. The following explanation uses the reduction of the analog-to-digital input signal as an example.

During the sampling phase, as shown in FIG. 6A, the portion of the main capacitor array with a capacitance of 1C is selected for sampling; that is, the corresponding capacitor receives the analog input signal Vinp, while the remaining capacitors are grounded. At this time, the charge magnitude Q₆₁ₚ in MAIN_CAP_UP and CAL_CAP_UP satisfies:

$$\begin{matrix}{Q}_{61 p} = ( Vcm - Vinp ) \times 1 C + ( Vcm - 0 ) \times \\ ( \begin{matrix}4 C + 4 C + 2 C + 2 C + 1 C + 1 C + 1 C + 4 C + \\ 4 C + 2 C + 2 C + 1 C + 1 C + 1 C + 1 C\end{matrix} ) \\ = 32 C \times Vcm - Vinp \times 1 C .\end{matrix} \qquad ( 13 )$$

During the conversion phase, as shown in FIG. 6B, the capacitor set CAL_CAP_UP1 in the calibration capacitor array is assigned to MAIN_CAP_UP in the main capacitor array, and the capacitor set CAL_CAP_DN1 in the calibration capacitor array is assigned to MAIN_CAP_DN in the main capacitor array, with the allocation ratio shown in FIG. 6B. The equivalent main capacitor array after the allocation may be shown in FIGS. 6C and 6D.

Referring to FIG. 6C, after the combination, a portion of each capacitor set of the main capacitor array, i.e., a capacitor of 6C, 3C, 1.5C and 1.5C, respectively, is connected to Vref, and the remaining portion of each capacitor set is connected to Gnd. The remaining capacitor sets in the calibration capacitor array CAL_CAP are connected to Gnd (the calibration code is not considered for ease of explanation). At this time, the charge magnitude Q₆₂ₚ in MAIN_CAP_UP and CAL_CAP_UP satisfies:

$$\begin{matrix}{Q}_{62 p} = ( Vxp - Vref ) \times ( 6 C + 3 c + 1.5 C + 1.5 C ) + \\ ( Vxp - 0 ) \times ( 6 C + 3 c + 1.5 C + 1.5 C ) + \\ ( Vxp - 0 ) \times ( 2 C + 2 C + 1 C + 1 C + 1 C + 1 C ) \\ = Vxp \times 32 C - Vref \times 12 C .\end{matrix} \qquad ( 14 )$$

From Q₆₁ₚ=Q₆₂ₚ, it can be obtained that:

$$Vxp = Vcm - \frac{3}{4} ( \frac{1}{24} \times Vinp - \frac{1}{2} \times Vref ) . \qquad ( 15 )$$

When the comparison result is smaller, referring to FIG. 6D, the capacitors connected to Vref as shown in FIG. 6C remains unchanged, and the remaining portion of the capacitor set corresponding to the highest capacitance bit, a capacitor of 6C, is connected to Vref. At this time, the charge magnitude Q₆₃ₚ in MAIN_CAP_UP and CAL_CAP_UP satisfies:

$$\begin{matrix}{Q}_{63 p} = ( Vxp - Vref ) \times ( 6 C + 6 C + 3 C + 1.5 C + 1.5 C ) + \\ ( Vxp - 0 ) \times ( 3 c + 1.5 C + 1.5 C ) + \\ ( Vxp - 0 ) \times ( 2 C + 2 C + 1 C + 1 C + 1 C + 1 C ) \\ = Vxp \times 32 C - Vref \times 18 C .\end{matrix} \qquad ( 16 )$$

From Q₆₁ₚ=Q₆₃ₚ, it can be obtained that:

$$Vxp = Vcm - \frac{3}{4} ( \frac{1}{24} \times Vinp - \frac{1}{2} \times Vref - \frac{1}{4} \times Vref ) ) . \qquad ( 17 )$$

Following the same logic:

$$Vxp = Vcm - \frac{3}{4} ( \frac{1}{24} \times Vinp - {\sum }_{i = 0}^{3} \frac{Vref}{{2}^{4 - i}} \times Di ) , \qquad ( 18 )$$

where Di represents the code value of the i-th capacitance bit, with the highest capacitance bit i being 3, the second highest bit i being 2, and so on.

Therefore, by multiplexing the capacitor set corresponding to the highest capacitance bit in the calibration capacitor array during the conversion phase, the analog input signal Vinp is reduced to 1/24 of its original value, and normal conversion may be achieved. When considering the calibration capacitor array having calibration compensation code values during the conversion process, the derivation process is similar as the above, except that the final successive approximation result is not proportional to the previous result because the calibration compensation code value is used for compensating the offset.

The present application also provides an analog-to-digital conversion method, which may be implemented using the analog-to-digital conversion circuit described above. The method includes: selecting a digital-to-analog conversion capacitor array and a calibration capacitor array based on a range control signal to sample and/or convert the analog input signal, so as to reduce or increase the analog input signal according to the ratio corresponding to the range control signal.

In the embodiments of the present application, the smaller the capacitance for sampling the analog input signal, the greater the reduction ratio; the larger the capacitance for sampling the analog input signal, the greater the increasement ratio; and the larger the capacitance for conversion, the greater the reduction ratio. In some examples, the capacitance for sampling may be increased by multiplexing a calibration capacitor array to increase the analog input signal. In some examples, the capacitance for conversion may be increased by multiplexing the calibration capacitor array to reduce the analog input signal. In some examples, the analog input signal may be reduced by decreasing the capacitance for sampling and increasing the capacitance for conversion by multiplexing the calibration capacitor array, thereby increasing the reduction ratio of the analog input signal, i.e., reducing the analog input signal to a smaller size. Furthermore, combinations of various capacitances for sampling and various capacitances for conversion may provide various reduction or increasement ratios, and more combinations may be achieved by multiplexing the calibration capacitor array, providing more reduction or increasement ratios.

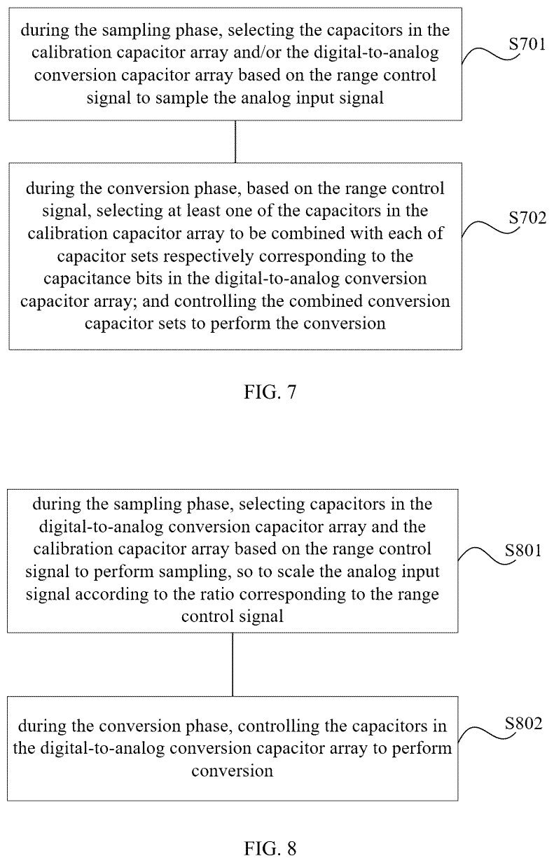

In some implementations, as shown in FIG. 7, the analog-to-digital conversion method includes steps S701 to S702.

In step S701, during the sampling phase, the capacitors in the calibration capacitor array and/or the digital-to-analog conversion capacitor array are selected based on the range control signal to sample the analog input signal.

As an example, during the sampling phase, one or more capacitors in the digital-to-analog conversion capacitor array may be selected based on a range control signal to sample the analog input signal. The smaller the capacitance of the selected capacitor, the greater the reduction ratio; that is, the smaller the capacitance for sampling, the smaller the analog-to-digital input signal is reduced. In this example, during the conversion phase, the calibration capacitor array may be controlled based on a calibration code for calibration.

As another example, during the sampling phase, one or more capacitors in the calibration capacitor array may be selected based on a range control signal to sample the analog input signal. The smaller the capacitance of the selected capacitor, the greater the reduction ratio; that is, the smaller the capacitance for sampling, the smaller the analog-to-digital input signal is reduced. In this example, the calibration capacitor array may be controlled for calibration based on a calibration code during the conversion phase.

As yet another example, during the sampling phase, one or more capacitors in the digital-to-analog conversion capacitor array 101 and one or more capacitors in the calibration capacitor array may be selected based on a range control signal to sample the analog input signal. The smaller the capacitance of the selected capacitor, the greater the reduction ratio; that is, the smaller the capacitance for sampling, the smaller the analog-to-digital input signal is reduced. In this example, the calibration capacitor array may be controlled based on a calibration code for calibration during the conversion phase.

In step S702, during the conversion phase, based on the range control signal, at least one of the capacitors in the calibration capacitor array is selected to be combined to each of the capacitor sets respectively corresponding to the capacitance bits in the digital-to-analog conversion capacitor array to increase the capacitance of each of the capacitor sets in the digital-to-analog conversion capacitor array, and the combined capacitor sets are controlled to perform the conversion.

In one implementation, in step S702, based on the range control signal, the capacitor of at least one capacitor set in the calibration capacitor array is selected and combined to each capacitor sets in the digital-to-analog conversion capacitor array. In another implementation, the capacitance ratio between the capacitor sets in the calibration capacitor array after the combination is the same as the capacitance ratio between the capacitor sets before combination.

As an implementation, a calibration may also be performed by controlling the unselected capacitor sets in the calibration capacitor array based on the calibration code.

In some implementations, as shown in FIG. 8, the method may include steps S801 to S802.

In step S801, during the sampling phase, capacitors in the digital-to-analog conversion capacitor array and the calibration capacitor array are selected based on the range control signal to perform sampling, so to scale the analog input signal according to the ratio corresponding to the range control signal.

In step S802, during the conversion phase, each capacitor in the digital-to-analog conversion capacitor array is controlled to perform conversion.

As an implementation, the calibration capacitor array may also be controlled based on the calibration code.

The present application also provides a chip that includes the analog-to-digital conversion circuit described above. The chip is also called an integrated circuit (IC), and may be, but is not limited to, a System-on-Chip (SoC) chip or a System-in-Package (SIP) chip. This chip may achieve a large range of scaling of analog input signals with a relatively small circuit area.

The present application also provides an electronic device, which includes a device body and a chip as described above disposed within the device body. The electronic device may be, but is not limited to, a weight scale, body fat scale, nutrition scale, infrared electronic thermometer, pulse oximeter, body composition analyser, power bank, wireless charger, fast charger, car charger, adapter, display, universal serial bus (USB) docking station, stylus, true wireless earphones, car infotainment screen, automobile, smart wearable device, mobile terminal, and smart home device. Smart wearable devices include, but are not limited to, smartwatches, smart bracelets, and neck massagers. Mobile terminals include, but are not limited to, smartphones, laptops, tablets, and point of sales terminal (POS) machines. Smart home devices include, but are not limited to, smart sockets, smart rice cookers, smart robot vacuums, and smart lights. This electronic device may achieve a large range of scaling of analog input signals with a relatively small circuit area.

The above are merely some embodiments of the present application and are not intended to limit the present application in any way. Although the present application has disclosed some embodiments as above, it is not intended to limit the present application. Any person skilled in the art can make some modifications or alterations to the above-disclosed technical content to create equivalent embodiments without departing from the scope of the technical solution of the present application. Any simple modifications, equivalent changes and alterations made to the above embodiments based on the technical essence of the present application without departing from the scope of the technical solution of the present application shall still fall within the scope of the technical solution of the present application.

What is claimed is:

1. An analog-to-digital conversion circuit, comprising:
a digital-to-analog conversion capacitor array;
a calibration capacitor array for calibrating the digital-to-analog conversion capacitor array; and
a logic controller for selecting the digital-to-analog conversion capacitor array and the calibration capacitor array based on a range control signal to sample and/or convert an analog input signal, to reduce or increase the analog input signal according to a ratio corresponding to the range control signal.

2. The analog-to-digital conversion circuit according to claim 1, wherein the logic controller is configured to: during a conversion phase,
select at least one of a plurality of calibration capacitors in the calibration capacitor array, based on the range control signal, for combination with each of a plurality of conversion capacitor sets respectively corresponding to a plurality of first capacitance bits in the digital-to-analog conversion capacitor array, to increase a capacitance of the each of the conversion capacitor sets; and
control the each of the conversion capacitor sets combined with the at least one of the calibration capacitors to convert the analog input signal.

3. The analog-to-digital conversion circuit according to claim 2, wherein the plurality of calibration capacitors are distributed among a plurality of calibration capacitor sets respectively corresponding to a plurality of second capacitance bits in the calibration capacitor array, and the at least one of the calibration capacitors is contained in at least one of the calibration capacitor sets.

4. The analog-to-digital conversion circuit according to claim 3, wherein the logic controller is further configured to control ones of the calibration capacitor sets other than the at least one of the calibration capacitor sets based on a calibration code.

5. The analog-to-digital conversion circuit according to claim 2, wherein the logic controller is further configured to, during a sampling phase, select one or more of the calibration capacitors and/or one or more of the conversion capacitors based on the range control signal to sample the analog input signal.

6. The analog-to-digital conversion circuit according to claim 2, wherein the logic controller is further configured to: during the conversion phase,
for any one of the conversion capacitor sets connected to a reference voltage terminal, connect the at least one of the calibration capacitors combined with the any one of the conversion capacitor sets to the reference voltage terminal; and
for any grounded one of the conversion capacitor sets, ground the at least one of the calibration capacitors combined with the any grounded one of the conversion capacitor sets.

7. The analog-to-digital conversion circuit according to claim 2, wherein the conversion capacitor sets after the combination have a same capacitance ratio as the conversion capacitor sets before the combination.

8. The analog-to-digital conversion circuit according to claim 1, wherein the logic controller is configured to:
during a sampling phase, select at least one of a plurality of conversion capacitors in the digital-to-analog conversion capacitor array and at least one of a plurality of calibration capacitors in the calibration capacitor array based on the range control signal to sample the analog input signal, to increase the analog input signal according to the ratio; and
during a conversion phase, control the conversion capacitors to convert the analog input signal.

9. The analog-to-digital conversion circuit according to claim 1, wherein the logic controller is further configured to control the calibration capacitor array based on a calibration code.

10. A chip comprising an analog-to-digital conversion circuit, the analog-to-digital conversion circuit comprising:
a digital-to-analog conversion capacitor array;
a calibration capacitor array for calibrating the digital-to-analog conversion capacitor array; and
a logic controller for selecting the digital-to-analog conversion capacitor array and the calibration capacitor array based on a range control signal to sample and/or convert an analog input signal, to reduce or increase the analog input signal according to a ratio corresponding to the range control signal.

11. The chip according to claim 10, wherein the logic controller is configured to: during a conversion phase,
select at least one of a plurality of calibration capacitors in the calibration capacitor array, based on the range control signal, for combination with each of a plurality of conversion capacitor sets respectively corresponding to a plurality of first capacitance bits in the digital-to-analog conversion capacitor array, to increase a capacitance of the each of the conversion capacitor set; and
control the each of the conversion capacitor sets combined with the at least one of the calibration capacitors to convert the analog input signal.

12. The chip according to claim 11, wherein the plurality of calibration capacitors are distributed among a plurality of calibration capacitor sets respectively corresponding to a plurality of second capacitance bits in the calibration capacitor array, and the at least one of the calibration capacitors is contained in at least one of the calibration capacitor sets.

13. The chip according to claim 12, wherein the logic controller is further configured to control ones of the calibration capacitor sets other than the at least one of the calibration capacitor sets based on a calibration code.

14. The chip according to claim 11, wherein the logic controller is further configured to, during a sampling phase, select one or more of the calibration capacitors and/or one or more of the conversion capacitors based on the range control signal to sample the analog input signal.

15. The chip according to claim 11, wherein the logic controller is further configured to: during the conversion phase,
for any one of the conversion capacitor sets connected to a reference voltage terminal, connect the at least one of the calibration capacitors combined with the any one of the conversion capacitor sets to the reference voltage terminal; and
for any grounded one of the conversion capacitor sets, ground the at least one of the calibration capacitors combined with the any grounded one of the conversion capacitor sets.

16. The chip according to claim 11, wherein the conversion capacitor set after the combination have a same capacitance ratio as the conversion capacitor sets before the combination.

17. The chip according to claim 10, wherein the logic controller is configured to:
during a sampling phase, select at least one of a plurality of conversion capacitors in the digital-to-analog conversion capacitor array and at least one of a plurality of calibration capacitors in the calibration capacitor array based on the range control signal to sample the analog input signal, to increase the analog input signal according to the ratio; and
during a conversion phase, control the conversion capacitors to convert the analog input signal.

18. The chip according to claim 10, wherein the logic controller is further configured to control the calibration capacitor array based on a calibration code.

19. An electronic device, comprising:
a device body; and
the chip according to claim 10, disposed in the device body.

20. An analog-to-digital conversion method, comprising:
selecting, based on a range control signal, a digital-to-analog conversion capacitor array and a calibration capacitor array to sample and/or convert an analog input signal, to reduce or increase the analog input signal according to a ratio corresponding to the range control signal,
wherein the calibration capacitor array is configured to calibrate the digital-to-analog conversion capacitor array.
